(19) United States
(12) Patent Application Publication
(10) Pub. No.: US 2021/0367564 A1
(43) Pub. Date: Nov. 25, 2021

(54) Linearization of Non-Linear Amplifiers

(71) Applicant: Telefonaktiebolaget LM Ericsson (publ), Stockholm (SE)

(72) Inventors: Katharina Hausmair, Göteborg (SE); Thomas Eriksson, Göteborg (SE); Christian Fager, Mölnlycke (SE); Ulf Gustavsson, Göteborg (SE)

(21) Appl. No.: 16/963,295

(22) PCT Filed: Jan. 24, 2018
(86) PCT No.: PCT/EP2018/051667

§ 371 Date: Jul. 20, 2020

(51) Int. Cl. H03F 1/32; H03F 3/24; H04B 1/16

(52) U.S. Cl. CPC H03F 1/3247; H03F 2200/451; H04B 1/16; H03F 3/245

(57) ABSTRACT

A linearization device (380) is disclosed, which is configured to determine pre-distortion parameters associated with a plurality of non-linear amplifiers (331, 332, 333, 334). Each of the non-linear amplifiers is associated with one of a plurality of transmit antenna elements and with a non-linear transfer function defining an output of the non-linear amplifier based on an input of the non-linear amplifier and based on a reflection signal for the non-linear amplifier, resulting from mutual couplings among the plurality of transmit antenna elements. The linearization device comprises a first port (381), a second port (382), and determination circuitry (383). The first port is configured to receive a plurality of channel coefficients indicative of channel characteristics of a plurality of communication paths between the plurality of non-linear amplifiers and two or more transmit observation receivers (370, 371, 372). Each transmit observation receiver is configured to receive a sum of transmission signals generated by the plurality of non-linear amplifiers and transferred over the communication paths between the plurality of non-linear amplifiers and the transmit observation receiver. The second port is configured to receive the sums of transmission signals from the transmit observation receivers. The determination circuitry is configured to determine the pre-distortion parameters based on the received plurality of channel coefficients, the received sums of transmission signals, and a model of the non-linear transfer functions of the non-linear amplifiers.

### TECHNICAL FIELD

The present disclosure relates generally to the field of wireless communication. More particularly, it relates to linearization of non-linear amplifiers.

### BACKGROUND

Large multi-antenna systems (e.g. advanced antenna systems, AAS) are increasingly applied in wireless communication, for example, in relation to fifth generation (5G) systems such. A wireless transmitter node (e.g. a radio base station, RBS) equipped with multiple (potentially tens, hundreds, or even more) transmitter branches entails both challenges and opportunities in terms of radio signal processing as is well known in the art.

One challenge is that of increased implementation complexity, particularly regarding the parts of the wireless transmitter node which are associated with radio signal processing (e.g. digital pre-distortion, DPD). One cost of implementation associated with DPD is the transmit observation receiver (TOR), or transmit observation receivers, which is used for monitoring power amplifier output and to extract measurement data for the DPD.

FIG. 1 schematically illustrates an example arrangement according to the prior art where each individual transmitter branch (1, b, . . . , n) is monitored by a dedicated TOR 114a, 114b, . . . , 114n. The output of each power amplifier (PA) 112a, 112b, . . . , 112n is provided to an antenna array 120 for transmission, and is fed back to the respective TOR 114a, 114b, . . . , 114n using a respective circulator 116a, 116b, . . . , 116n and a respective directional coupler 115a, 115b, . . . , 115n.

The signal received by the respective TOR 114a, 114b, . . . , 114n is provided to a respective parameter estimator 113a, 113b, . . . , 113n, which estimates parameters to be used by a respective actuator 111a, 111b, . . . , 111n for digital pre-distortion of a signal input to the respective PA 112a, 112b, . . . , 112n with the aim of compensating for non-linarites of the respective PA 112a, 112b, . . . , 112n.

The solution of FIG. 1 becomes increasingly complex as the number of transmit antenna elements, and thereby the number of transmitter branches, increases since the number of TOR:s increases in the same manner.

FIG. 2 schematically illustrates an example arrangement according to the prior art where the transmitter branches (1, b, . . . , n) are monitored by a shared TOR 214. The output of each power amplifier (PA) 212a, 212b, . . . , 212n is provided to an antenna array 220 for transmission, and is fed back to the shared TOR 214 using a respective circulator 216a, 216b, . . . , 216n and a respective directional coupler 215a, 215b, . . . , 215n.

The signal received by the shared TOR 214 is provided to a parameter estimator 213, which estimates parameters to be used by a respective actuator 211a, 211b, . . . , 211n for digital pre-distortion of a signal input to the respective PA 212a, 212b, . . . , 212n with the aim of compensating for non-linarites of the respective PA 212a, 212b, . . . , 212n.

The sharing of the TOR 214 between the transmitter branches may be accomplished by software controlled switchable networks 210, 217 or by any other suitable approach.

The solution of FIG. 2 also becomes increasingly complex as the number of transmit antenna elements, and thereby the number of transmitter branches, increases since the sharing (e.g. the software controlled switchable networks) becomes increasingly complex.

Typically, traditional solutions implement an approach where each individual transmitter branch is monitored either by a dedicated TOR (as illustrated in FIG. 1) or by a TOR shared with other transmitter branches via a switch and a lossy distribution network (as illustrated in FIG. 2). In either case, the implementation is costly in terms of active hardware and signal routing and distribution, which becomes increasingly cumbersome for an increasing number or transmitter branches (i.e. as the number of transmit antenna elements increases).

Thus, pre-distortion (DPD) approaches of the prior art suffers from complexity issues; in terms of the number of TOR:s and/or in terms of the size of the switchable networks for TOR sharing. Furthermore, the approaches in FIGS. 1 and 2 both require individual directional couplers per transmitter branch, which typically increases both size and cost of the implementation, and introduces additional losses.

Another issue encountered for conventional pre-distortion (DPD) approaches is the effects emanating from mutual coupling between antennas; see for example S. Choi, E.-R. Jeong; “Digital Predistortion Based on Combined Feedback in MIMO Transmitters”, IEEE Communication Letters, vol. 16, no. 10, pp. 1572-1575, October 2012.

Therefore, there is a need for novel and alternative approaches to linearization of non-linear amplifiers. Preferably, approaches which are less complex than solutions of the prior art when applied to large antenna arrays and which also provides handling of mutual coupling between antennas.

### SUMMARY

It should be emphasized that the term “comprises/comprising” when used in this specification is taken to specify the presence of stated features, integers, steps, or components, but does not preclude the presence or addition of one or more other features, integers, steps, components, or groups thereof. As used herein, the singular forms “a”, “an” and “the” are intended to include the plural forms as well, unless the context clearly indicates otherwise.

It is an object of some embodiments to solve or mitigate, alleviate, or eliminate at least some of the above or other disadvantages.

According to a first aspect, this is achieved by a linearization device configured to determine pre-distortion parameters associated with a plurality of non-linear amplifiers. Each of the non-linear amplifiers is associated with one of a plurality of transmit antenna elements and with a non-linear transfer function defining an output of the non-linear amplifier based on an input of the non-linear amplifier and based on a reflection signal for the non-linear amplifier, resulting from mutual couplings among the plurality of transmit antenna elements.

The linearization device comprises a first port configured to receive a plurality of channel coefficients indicative of channel characteristics of a plurality of communication paths between the plurality of non-linear amplifiers and two or more transmit observation receivers. Each transmit observation receiver is configured to receive a sum of transmission signals generated by the plurality of non-linear amplifiers and transferred over the communication paths between the plurality of non-linear amplifiers and the transmit observation receiver.

The linearization device also comprises a second port configured to receive the sums of transmission signals from the transmit observation receivers.

Furthermore, the linearization device also comprises determination circuitry configured to determine the pre-distortion parameters based on the received plurality of channel coefficients, the received sums of transmission signals, and a model of the non-linear transfer functions of the non-linear amplifiers.

In some embodiments, the model is represented, for each of the non-linear amplifiers, by a plurality of amplifying coefficients in a space spanned by a regression matrix of the inputs and the reflection signals.

In some embodiments, each reflection signal is modelled as a linear function of the outputs of the plurality of non-linear amplifiers, the linear function being defined by reflection coefficients.

In some embodiments, the determination circuitry is further configured to determine the reflection coefficients by defining initial reflection coefficients, determining intermediate amplifying coefficients based on the initial reflection coefficients, determining intermediate reflection coefficients based on the intermediate amplifying coefficients, and recursively determining refined amplifying coefficients based on previous reflection coefficients and refined reflection coefficients based on previous amplifying coefficients.

In some embodiments, the linearization device is configured to determine the pre-distortion parameters based on the amplifying coefficients.

In some embodiments, the linearization device is configured to determine the amplifying coefficients based on N samples of the sums of transmission signals received by the transmit observation receivers via L receive antenna ports by determining, for each of the plurality of non-linear amplifiers, a Kronecker product between a column vector having as elements the corresponding estimated channel coefficients and the regression matrix, calculating a generalized pseudo-inverse of a matrix formed by concatenating the determined Kronecker products of the plurality of non-linear amplifiers, and determining a matrix product between the calculated generalized pseudo-inverse and a column vector having as elements the N samples of the sums of transmission signals from each of the L receive antenna ports.

In some embodiments, the plurality of communication paths are radio communication paths between the plurality of non-linear amplifiers and the transmit observation receivers via a corresponding plurality of transmit antenna elements and at least two receive antenna elements.

A second aspect is an arrangement for a wireless transmitter node, the wireless transmitter node comprising at least two receive antenna ports, each connectable to a corresponding receive antenna element, and a plurality of transmit antenna ports, each connectable to a corresponding transmit antenna element of an active antenna array having a plurality of transmit antenna elements.

Each transmit antenna port is associated with a respective transmitter branch, wherein each transmitter branch comprises a non-linear amplifier and digital pre-distortion circuitry.

The non-linear amplifier is associated with one of the plurality of transmit antenna elements and with a non-linear transfer function defining an output of the non-linear amplifier based on an input of the non-linear amplifier and based on a reflection signal for the non-linear amplifier, resulting from mutual couplings among the plurality of transmit antenna elements.

The digital pre-distortion circuitry is configured to compensate the non-linear transfer function by pre-distorting the signal of the transmitter branch based on pre-distortion parameters.

The arrangement comprises a channel estimator, two or more transmit observation receivers, and the linearization device of the first aspect.

The channel estimator is configured to estimate a plurality of channel coefficients indicative of channel characteristics of a plurality of communication paths between the plurality of non-linear amplifiers and two or more transmit observation receivers.

Each of the two or more transmit observation receivers is associated with one of the at least two receive antenna ports and configured to receive a sum of transmission signals generated by the plurality of non-linear amplifiers and transferred over the communication paths between the plurality of non-linear amplifiers and the transmit observation receiver.

The linearization device has the first port connected to the channel estimator and the second port connected to the transmit observation receiver. Furthermore, the linearization device is configured to provide the determined pre-distortion parameters to the digital pre-distortion circuitry of the transmitter branches.

In some embodiments, the arrangement further comprises the at least two receive antenna ports and the at least two receive antenna elements.

A third aspect is a wireless transmitter node comprising at least one of the linearization device of the first aspect and the arrangement of the second aspect.

A fourth aspect is a cloud based server node comprising the linearization device of the first aspect, wherein the cloud based server node is configured to provide the determined pre-distortion parameters to a wireless transmitter node.

A fifth aspect is a method for a linearization device for determining pre-distortion parameters associated with a plurality of non-linear amplifiers, each associated with one of a plurality of transmit antenna elements and with a non-linear transfer function defining an output of the non-linear amplifier based on an input of the non-linear amplifier and based on a reflection signal for the non-linear amplifier, resulting from mutual couplings among the plurality of transmit antenna elements.

The method comprises receiving, via a first port of the linearization device, a plurality of channel coefficients indicative of channel characteristics of a plurality of communication paths between the plurality of non-linear amplifiers and two or more transmit observation receivers, wherein each transmit observation receiver is configured to receive a sum of transmission signals generated by the plurality of non-linear amplifiers and transferred over the communication paths between the plurality of non-linear amplifiers and the transmit observation receiver.

The method also comprises receiving, via a second port of the linearization device, the sums of transmission signals from the transmit observation receiver, and determining the pre-distortion parameters based on the received plurality of channel coefficients, the received sums of transmission signals, and a model of the non-linear transfer functions of the non-linear amplifiers.

In some embodiments, the method further comprises estimating the plurality of channel coefficients.

A sixth aspect is a computer program product comprising a non-transitory computer readable medium, having thereon a computer program comprising program instructions. The computer program is loadable into a data processing unit and configured to cause execution of the method according to the fifth aspect when the computer program is run by the data processing unit.

In some embodiments, any of the above aspects may additionally have features identical with or corresponding to any of the various features as explained above for any of the other aspects.

An advantage of some embodiments is that a lower complexity may be achieved than for approaches according to the prior art, in particular for an increasing number of transmit antenna elements. The complexity may, for example, be defined in terms of one or more of: the number of TOR:s, the complexity (e.g. size) of a switching network, and the number of directional couplers.

Another advantage of some embodiments is that mutual coupling between antennas can be taken into account. Typically, this advantage leads to a higher accuracy of the linearization.

### BRIEF DESCRIPTION OF THE DRAWINGS

Further objects, features and advantages will appear from the following detailed description of embodiments, with reference being made to the accompanying drawings. The drawings are not necessarily to scale, emphasis instead being placed upon illustrating the example embodiments.

FIG. 1 is a schematic block diagram illustrating an example arrangement according to the prior art;

FIG. 2 is a schematic block diagram illustrating an example arrangement according to the prior art;

FIG. 3 is a schematic block diagram illustrating an example arrangement according to some embodiments;

FIG. 4 is a flowchart illustrating example method steps according to some embodiments;

and

FIG. 5 is a schematic drawing illustrating an example computer readable medium according to some embodiments.

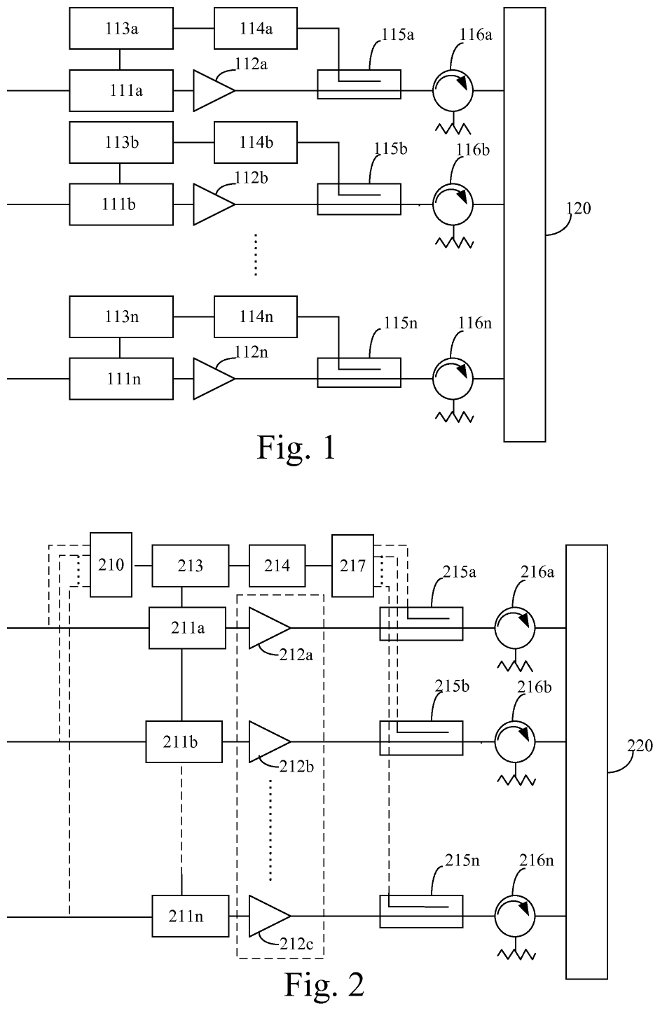

### DETAILED DESCRIPTION

As already mentioned above, it should be emphasized that the term “comprises/comprising” when used in this specification is taken to specify the presence of stated features, integers, steps, or components, but does not preclude the presence or addition of one or more other features, integers, steps, components, or groups thereof. As used herein, the singular forms “a”, “an” and “the” are intended to include the plural forms as well, unless the context clearly indicates otherwise.

Embodiments of the present disclosure will be described and exemplified more fully hereinafter with reference to the accompanying drawings. The solutions disclosed herein can, however, be realized in many different forms and should not be construed as being limited to the embodiments set forth herein.

In the following, embodiments will be described where two or more TOR:s can be used in connection to determination of pre-distortion parameters for a plurality of transmitter branches without the need for directional couplers or switching networks.

Embodiment presented herein also provides for handling of the issue encountered for conventional pre-distortion (DPD) approaches; the effects emanating from mutual coupling between antennas. To this end, some embodiments accommodate a need for isolation between transmit branches to cope with the effects of mutual coupling. It may be noted that existing solutions for reduced analog hardware complexity in pre-distortion (DPD) approaches take mutual coupling between antennas into consideration.

This is achieved by (simultaneous) observation of at least two sums of transmission signals, wherein each transmission signal is generated by a respective one of a plurality of non-linear amplifiers and is transferred over the communication path between the non-linear amplifier and the corresponding transmit observation receiver. The channel coefficients indicative of channel characteristics of the plurality of communication paths between the plurality of non-linear amplifiers and the transmit observation receivers may be estimated by any suitable method or may be otherwise known.

The pre-distortion parameters are then determined for the plurality of transmitter branches based on the channel coefficients, the received sums of transmission signals, and a model of non-linear transfer functions of the non-linear amplifiers.

Some embodiments thus provide simplified pre-distortion for antenna arrays with mutual coupling. Embodiments presented herein uses few—typically much fewer than the number of transmission branches—TOR:s (each connected to an observation receiver) to simultaneously identify the pre-distortion parameters for a larger number of different transmit branches, thereby saving cost and/or implementation complexity. Thus, according to some embodiments, the amount of measurement receivers needed to compensate for power amplifier distortion in a large array is reduced compared to prior art approaches.

Furthermore, the mutual coupling between transmit antenna elements is taken into account in the pre-distortion parameter determination as exemplified herein.

FIG. 3 schematically illustrates an example arrangement 300 for a wireless transmitter node according to some embodiments. The wireless transmitter node comprises at least two receive antenna ports 355, 356, 357, each connectable to a corresponding receive antenna element 350, 351, 352, and a plurality (exemplified as four in FIG. 3 for illustration) of transmit antenna ports 345, 346, 347, 348, each connectable to a corresponding transmit antenna element of an active antenna array having a plurality of transmit antenna elements 341, 342, 343, 344.

Each transmit antenna port is associated with a respective transmitter branch, wherein each transmitter branch comprises a non-linear power amplifier (PA) 331, 332, 333, 334 associated with a non-linear transfer function and configured to amplify a signal of the transmitter branch.

The non-linear transfer function defines an output of the non-linear amplifier based on an input of the non-linear amplifier and based on a reflection signal for the non-linear amplifier, resulting from mutual couplings among the plurality of transmit antenna elements.

Each transmitter branch also comprises digital pre-distortion circuitry (DPD) 321, 322, 323, 324 configured to compensate the non-linear transfer function by pre-distorting the signal of the transmitter branch based on pre-distortion parameters.

The pre-distortion circuitry may, for example, comprise respective pre-distortion circuitry for each of the transmitter branches as illustrated in FIG. 3 or common pre-distortion circuitry shared for all of the transmitter branches (see e.g. 320 of FIG. 3). Generally, the pre-distortion circuitry may comprise one or more actuators.

In one typical example, a multi-antenna transmitter DPD (a common pre-distortion circuitry) 320 may comprise one dual-input DPD per transmission branch (the dual inputs being a signal input and a crosstalk input), and one shared crosstalk mismatch model (CTMM) 325 taking the signal input of each DPD as inputs and providing the crosstalk inputs (estimates of the reflected signals) to each DPD. The CTMM may include the coupling (reflection) coefficients for all M transmit paths, the m^{th} dual-input DPD may include DPD coefficients (parameters) for the corresponding PA, and all coefficients are identified (and updated if there is an adaptive algorithm used) by the linearization device 380.

A signal to be transmitted is divided into respective signals to be transmitted by each transmitter branch by a transmit pre-coder (TPC) 310 according to any suitable approach. It may be preferable that the signal to be transmitted comprises a wide range of signal properties (e.g. different amplitudes and/or different frequencies), since such diverse signal properties provides for proper linearization of the non-linear amplifiers.

Typically, but not necessarily, the arrangement 300 is implemented in a different hardware unit than the transmitter branches.

The arrangement 300 comprises at least two transmit observation receivers (TOR) 370, 371, 372, each associated with one of the receive antenna ports 355, 356, 357 and configured to receive a sum of transmission signals generated by the plurality of non-linear amplifiers and transferred over a plurality of communication paths 391, 392, 393, 394 (e.g. radio communication paths) between the plurality of non-linear amplifiers and the transmit observation receiver. In FIG. 3, only the communication paths 391, 392, 393, 394 between the plurality of non-linear amplifiers and the transmit observation receiver 370 have been labeled with reference numbers. The communication paths between the plurality of non-linear amplifiers and the other transmit observation receivers 371, 372 are illustrated ad dotted lines without reference number labels.

If the reflection coefficients (thus, at least implicitly, the mutual couplings among the plurality of transmit antenna elements is known) are known, already estimated, or otherwise in no need for being estimated, the arrangement comprises at least two (for example exactly two) transmit observation receivers (TOR).

If the reflection coefficients (and implicitly the mutual couplings among the plurality of transmit antenna elements) are not known, not estimated, or otherwise in need for being estimated, the arrangement comprises at least three (for example exactly three) transmit observation receivers (TOR).

Thus, the wireless transmitter node may comprise two or more receive antenna ports (e.g. as many receive antenna ports as it comprises transmit antenna ports). Typically, a convergence time of the linearization process to be described herein decreases as the number of receive antenna ports increases.

The arrangement 300 also comprises a channel estimator (CE) 360 configured to estimate a plurality of channel coefficients indicative of channel characteristics of the plurality of communication paths.

In various embodiments, the arrangement may also comprise some or all of: the at least two receive antenna ports 355, 356, 357, the at least one receive antenna element 350, 351, 352, the plurality of transmit antenna ports 345, 345, 347, 348, the active antenna array comprising the transmit antenna elements 341, 342, 343, 344, and the transmitter branches.

The arrangement 300 also comprises a linearization device (LIN; e.g. linearization circuitry) 380. The linearization device 380 is configured to determine the pre-distortion parameters associated with the non-linear amplifiers 331, 332, 333, 334 to be used by the digital pre-distortion circuitry 321, 322, 323, 324. To this end, the linearization device comprises a first port 381, a second port 382 and determination circuitry (DET) 383.

Generally, when a linearization device is referred to herein, a linearization device may be defined as a device which is configured to compensate for a distortion in a signal introduced by one or more non-linear components in a radio system. A non-linear component is a component which has an output that is not a linear function of an input of the component. An example of a non-linear component is a non-linear power amplifier, such as the power amplifiers discussed in connection to FIG. 3. As mentioned above, each of the non-linear power amplifiers is associated with a non-linear transfer function defining an output of the non-linear amplifier based on an input of the non-linear amplifier and based on a reflection signal for the non-linear amplifier, resulting from mutual couplings among the plurality of transmit antenna elements. Thus, the mutual coupling among the plurality of transmit antenna elements is considered generally herein as subject to the linearization.

The first port 381 is configured to receive a plurality of channel coefficients indicative of channel characteristics of the plurality of communication paths 391, 392, 393, 394 between the plurality of non-linear amplifiers and the transmit observation receivers 370, 371, 372. In the embodiment of FIG. 3, the channel coefficients are estimated by and received from the channel estimator 360. It should be noted that the channel coefficients may be determined or estimated in any suitable manner. In some embodiments, the channel coefficients may even be known beforehand.

Generally, when channel coefficients are referred to herein, the channel coefficients may be defined according to any suitable, known or future, approach. For example, each channel coefficient may refer to a complex value which describes a difference (in terms of amplitude and phase) between a transmitted signal and a part of the corresponding signal received at a particular time, wherein different channel coefficients refer to different particular times to, e.g. to describe a multipath channel model which in this case is a model of the plurality of communication paths 391, 392, 393, 394 between the plurality of non-linear amplifiers and the transmit observation receivers 370, 371, 372. Thus, the channel estimation referred to herein is not for access purposes (as is typically the case for channel estimation), but is an estimation of the channel comprising the plurality of communication paths 391, 392, 393, 394 between the plurality of non-linear amplifiers and the transmit observation receiver 370.

Also generally, the communication paths may be wireless (e.g. radio) communication paths and the linearization may be based on over-the-air measurements.

The second port 382 linearization device is configured to receive the sums of transmission signals from the transmit observation receivers 370, 371, 372, and the determination circuitry 383 is configured to determine the pre-distortion parameters based on the received plurality of channel coefficients, the received sums of transmission signals, and a model of the non-linear transfer functions of the non-linear amplifiers.

In the embodiment of FIG. 3, the first port 381 is connected to the channel estimator and the second port 382 is connected to the transmit observation receivers. The linearization device is configured to provide the determined pre-distortion parameters, and the determined reflection coefficients (if applicable), to the digital pre-distortion circuitry of the transmitter branches as illustrated by 384 in FIG. 3.

In FIG. 3, the linearization device 380 (and the arrangement 300) has been illustrated as comprised in a wireless transmitter node. It should be noted that, in other embodiments, the linearization device 380 may be comprised in another node, for example a cloud based server node. In such embodiments, the other node may be configured to provide the determined pre-distortion parameters to a wireless transmitter node for application therein.

Alternatively or additionally, the channel estimator 360 may be comprised in another node than the wireless transmitter node (which other node may be the same or different than the node comprising the linearization device). In such embodiments, the node comprising the channel estimator may be configured to provide the channel coefficients to the node comprising the linearization device for application therein. In fact, the channel coefficients may not even be provided by a channel estimator according to some embodiments, but may be acquired in some other way (e.g. known beforehand).

The determination, by the linearization device, of the pre-distortion parameters will be exemplified in the following. In this context it should be noted that some embodiments provide an approach wherein it is possible to determine the pre-distortion parameters from the sum of transmission signals; i.e. it may not be necessary, or even possible, to separate the individual transmission signals of each respective transmitter branch.

In the following example of the determination of the pre-distortion parameters, it is assumed that there are M transmitter branches, each with a respective non-linear amplifier, the index m identifying the relevant transmitter branch and amplifier, and that there are L receiver ports, each with a respective TOR, the index l identifying the relevant receiver port.

The output from the m^{th} amplifier may be modeled using a non-linear transfer function which describes the input-output relation of the non-linear amplifier. The non-linear transfer function for the m^{th} amplifier defines an output b₂ₘ, 302, of the non-linear amplifier based on an input a₁ₘ, 301, of the non-linear amplifier and based on a reflection signal a₂ₘ, 303, for the non-linear amplifier (the reflected wave injected via mutual coupling), wherein the reflection signal results from mutual couplings among the plurality of transmit antenna elements. The non-linear transfer function for the m^{th} amplifier may be written as: b₂ₘ=ƒₘ(a₁ₘ, a₂ₘ).

The above expression of the non-linear transfer function for the m^{th} amplifier may be written in linear matrix-vector form as: b₂ₘ=G(a₁ₘ, a₂ₘ)θₘ, where θₘ is a vector of amplifying coefficients θⱼₘ in a (possibly polynomial) model for the m^{th} amplifier, and G(a₁ₘ, a₂ₘ) is the regression matrix of the m^{th} amplifier (in many cases the regression matrix may be considered to be equal for all amplifiers).

The regression matrix represents a model of the non-linear amplifier. The model is represented by a plurality of amplifying coefficients θⱼₘ in a space spanned by the regression matrix of the inputs and the reflection signals.

The reflection signal a₂ₘ may be expressed as a function of the M different outputs from the power amplifiers: a₂ₘ=hₘ(b₂₁, . . . , b_{2M}), where hₘ is a function describing the mutual coupling.

The reflection signal for the m^{th} amplifier may be expressed as a scalar product: a₂ₘ=b₂^{T}λₘ, where b₂=[b₂₁, b_{2M}]^{T} and Δₘ=[λₘ₁, . . . , λ_{mM}]^{T} is a vector of reflection coefficients modeling the mutual coupling between the m^{th} transmit antenna element and the other transmit antenna elements. Thus, each reflection signal may be modelled as a linear function (e.g. linear combination) of the outputs of the plurality of non-linear amplifiers, the linear function being defined by reflection coefficients.

The received signal at the l^{th} receiver port is measured as the sum: rₗ=Σₘ₌₁^{M}ηₗₘb₂ₘ, where ηₗₘ is the channel coefficient describing the wireless channel, 391, 392, 393, 304 between the m^{th} transmitter and the l^{th} TOR. Given the assumptions above, the received signal may be modelled as: rₗ=Σₘ₌₁^{M}ηₗₘG(a₁ₘ, a₂ₘ)θₘ.

Using a generalized system model (compare with FIG. 3) with L measurement receivers (i.e. L receiver antenna ports) and M transmitters, the measurement vector may be written as:

$$[ \begin{matrix}{r}_{1} \\ ⋮ \\ {r}_{L}\end{matrix} ] = ( \begin{matrix}[ {η}_{1} ⊗ G ( {a}_{11} , {a}_{21} ) & … & {η}_{M} ⊗ G ( {a}_{1 M} , {a}_{2 M} ) ] )\end{matrix} [ \begin{matrix}{θ}_{1} \\ ⋮ \\ {θ}_{M}\end{matrix} ] = [ \begin{matrix}{η}_{11} G ( {a}_{11} , {a}_{21} ) & ⋯ & {η}_{1 M} G ( {a}_{1 M} , {a}_{2 M} ) \\ ⋮ & ⋱ & ⋮ \\ {η}_{L1} G ( {a}_{11} , {a}_{21} ) & ⋯ & {η}_{LM} G ( {a}_{1 M} , {a}_{2 M} )\end{matrix} ] [ \begin{matrix}{θ}_{1} \\ ⋮ \\ {θ}_{M}\end{matrix} ]$$

where rₗ is the vector of N samples received at the l^{th} receive antenna port, η represents the channel coefficients, and [symbol] is the Kronecker-product.

Thus, [η₁ [symbol] G(a₁₁, a₂₁) . . . η_{M} [symbol] G(a_{1M}, a_{2M})] represents a concatenation of the Kronecker products (of the plurality of non-linear amplifiers) between a column vector having as elements the corresponding estimated channel coefficients and a regression matrix, and r represents N samples of the sum of transmission signals received by the transmit observation receiver via L receive antenna ports.

Provided that the reflection coefficients modeling the mutual coupling are known, procedure may be used to in identify the amplifier coefficients as:

$$= {[ \begin{matrix}{η}_{11} G ( {a}_{11} , {a}_{21} ) & ⋯ & {η}_{1 M} G ( {a}_{1 M} , {a}_{2 M} ) \\ ⋮ & ⋱ & ⋮ \\ {η}_{L1} G ( {a}_{11} , {a}_{21} ) & ⋯ & {η}_{LM} G ( {a}_{1 M} , {a}_{2 M} )\end{matrix} ]}^{†} [ \begin{matrix}{r}_{1} \\ ⋮ \\ {r}_{L}\end{matrix} ]$$

wherein [⋅]^{†} denotes the generalized pseudo-invers, and [symbol] denotes the least-square estimate of the coefficients.

The estimated amplifier coefficients thus provided may be used in a next step of an iterative procedure further refining the estimate of the amplifier coefficients.

An example of such an iterative procedure for estimating the amplifier coefficients can be illustrated by a pseudo-code function using known reflection coefficients and two over-the-air measurements (i.e. two transmit observation receivers, L=2) as follows, where NMSE denotes the normalized mean square error, and \tilde{B}_{2M}⁽⁰⁾ is an augmented N×M matrix consisting of all N×1-dimensional b₂ₘ vectors for all M transmit branches:

| known: | input signals a₁ₘ | |
|---|---|---|
| | reflection coefficients λₘ | |
| | channel coefficients η₁ₘ, η₂ₘ | |
| measured: | received signals r₁, r₂ | |
| NMSE_{des} = X, | | [define desired accuracy] |
| NMSE = ∞, | | |
| \tilde{B}_{2M}⁽⁰⁾ = 0, | | [set initial value of PA model] |
| i = 0, | | |
| while NMSE ≥ NMSE_{des} do | | [iterate to desired accuracy] |

i = i + 1,
For all M compute: ã₂ₘ⁽ⁱ⁾ = \tilde{B}_{2M}⁽ⁱ⁻¹⁾λₘ,
$[ \begin{matrix}{\tilde{θ}}_{1}^{( i )} \\ ⋮ \\ {\tilde{θ}}_{M}^{( i )}\end{matrix} ] = {[ \begin{matrix}{η}_{11} G ( {a}_{11} , {\tilde{a}}_{21}^{( i )} ) & … & {η}_{1 M} G ( {a}_{1 M} , {\tilde{a}}_{2 M}^{( i )} ) \\ {η}_{21} G ( {a}_{11} , {\tilde{a}}_{21}^{( i )} ) & … & {η}_{2 M} G ( {a}_{1 M} , {\tilde{a}}_{2 M}^{( i )} )\end{matrix} ]}^{†} [ \begin{matrix}{r}_{1} \\ {r}_{2}\end{matrix} ] ,$
\tilde{B}_{2M}⁽ⁱ⁾ = [G(a₁₁, ã₂₁⁽ⁱ⁾)\tilde{θ}₁⁽ⁱ⁾ . . . G(a_{1M}, ã_{2M}⁽ⁱ⁾)\tilde{θ}_{M}⁽ⁱ⁾],
[\tilde{r}₁⁽ⁱ⁾ \tilde{r}₂⁽ⁱ⁾] = \tilde{B}_{2M}⁽ⁱ⁾[η₁ η₂],
NMSE = max_{l=1,2} {NMSE(rₗ, \tilde{r}ₗ⁽ⁱ⁾)},

end while
θₘ = \tilde{θ}ₘ⁽ⁱ⁾.

If the reflection coefficients modeling the mutual coupling (e.g. due to cross talk and/or mismatch) are not known, they may be determined (i.e. estimated) using a recursive approach in which initial reflection coefficients are defined as an initial assumption. Such initial reflection coefficients may be selected using any suitable approach—For example, it may be initially assumed that there is no mutual coupling between the transmit antenna elements. Then, intermediate amplifying coefficients may be determined based on the initial reflection coefficients and intermediate reflection coefficients may be determined based on the intermediate amplifying coefficients, and so on until some stopping criterion is met (e.g. that the mean square error between subsequent recursions falls below a threshold value and/or that a maximum number of allowable recursions have been carried out).

An example of such a recursive approach for estimating the amplifier coefficients and the reflection coefficients can be illustrated by a pseudo-code function using three over-the-air measurements (i.e. three transmit observation receivers, L=3) as follows, where r is a 3N×1-dimensional vector, [⋅]* denotes the complex conjugate, P is the dimensionality of the polynomial model (indexed by p), and ƒₘ^{(⋅)} is a vector of N samples from all the corresponding ƒₘ^{(⋅)}:

| known: | input signals a₁ₘ | |
|---|---|---|
| | channel coefficients η₁ₘ, η₂ₘ, η₃ₘ | |
| measured: | received signals r = [r₁^{T}, r₂^{T}, r₃^{T}]^{T} | |
| NMSE_{des} = X, | | [define desired accuracy] |
| NMSE = ∞, | | |
| \tilde{λ}ₘ⁽⁰⁾ = 1, ã₂ₘ⁽⁰⁾ = 0 | | [set initial values] |
| i = 0, | | |
| while NMSE ≥ NMSE_{des} do | | [iterate to desired accuracy] |
| | i = i + 1, | |
| | STEP 1: | [find PA model coefficients] |
| | $[ \begin{matrix}{\tilde{θ}}_{1}^{( i )} \\ ⋮ \\ {\tilde{θ}}_{M}^{( i )}\end{matrix} ] = {[ \begin{matrix}{η}_{11} G ( {a}_{11} , {\tilde{a}}_{21}^{( i 1 )} ) & … & {η}_{1 M} G ( {a}_{1 M} , {\tilde{a}}_{2 M}^{( i 1 )} ) \\ {η}_{21} G ( {a}_{11} , {\tilde{a}}_{21}^{( i 1 )} ) & … & {η}_{2 M} G ( {a}_{1 M} , {\tilde{a}}_{2 M}^{( i 1 )} ) \\ {η}_{31} G ( {a}_{11} , {\tilde{a}}_{21}^{( i 1 )} ) & … & {η}_{3 M} G ( {a}_{1 M} , {\tilde{a}}_{2 M}^{( i 1 )} )\end{matrix} ]}^{†} [ \begin{matrix}{r}_{1} \\ {r}_{2} \\ {r}_{3}\end{matrix} ] ,$ | |
| | if i > 1 then | |
| | STEP 2: | [find reflection coefficients] |
| | fₘ⁽⁰⁾ = Σₚ₌₀^{(P-1)/2} \tilde{α}ₘₚ⁽ⁱ⁾a₁ₘ^{p+1}a₁ₘ^{*p}, | |
| | fₘ⁽¹⁾ = Σₚ₌₀^{(P-1)/2} \tilde{β}ₘₚ⁽ⁱ⁾a₁ₘ^{p}a₁ₘ^{*p}, | |
| | fₘ⁽²⁾ = Σₚ₌₀^{(P-1)/2} \tilde{γ}ₘₚ⁽ⁱ⁾a₁ₘ^{p+1}a₁ₘ^{*p-1}, | |
| | Fₘ⁽¹⁾ = diag{fₘ⁽¹⁾}\tilde{β}_{2M}⁽ⁱ⁻¹⁾, | |
| | Fₘ⁽²⁾ = diag{fₘ⁽²⁾}\tilde{β}_{2M}^{(i-1)*}, | |
| | ${f}^{( 0 )} = [ \begin{matrix}{η}_{11} {f}_{1}^{( 0 )} + … + {η}_{1 M} {f}_{M}^{( 0 )} \\ {η}_{21} {f}_{1}^{( 0 )} + … + {η}_{2 M} {f}_{M}^{( 0 )} \\ {η}_{31} {f}_{1}^{( 0 )} + … + {η}_{3 M} {f}_{M}^{( 0 )}\end{matrix} ] ,$ | |
| | ${F}^{( 1 )} = [ \begin{matrix}{η}_{11} {F}_{1}^{( 1 )} & … & {η}_{1 M} {F}_{M}^{( 1 )} \\ {η}_{21} {F}_{1}^{( 1 )} & … & {η}_{2 M} {F}_{M}^{( 1 )} \\ {η}_{31} {F}_{1}^{( 1 )} & … & {η}_{3 M} {F}_{M}^{( 1 )}\end{matrix} ] ,$ | |
| | ${F}^{( 2 )} = [ \begin{matrix}{η}_{11} {F}_{1}^{( 2 )} & \text{…} & {η}_{1 M} {F}_{M}^{( 2 )} \\ {η}_{21} {F}_{1}^{( 2 )} & \text{…} & {η}_{2 M} {F}_{M}^{( 2 )} \\ {η}_{31} {F}_{1}^{( 2 )} & \text{…} & {η}_{3 M} {F}_{M}^{( 2 )}\end{matrix} ] ,$ | |
| | $[ \begin{matrix}Re \{ {\tilde{λ}}^{( 1 )} \} \\ Im \{ {\tilde{λ}}^{( 1 )} \}\end{matrix} ] = {[ \begin{matrix}Re \{ {F}^{( 1 )} + {F}^{( 2 )} \} & Im \{ - {F}^{( 1 )} + {F}^{( 2 )} \} \\ Im \{ {F}^{( 1 )} + {F}^{( 2 )} \} & Re \{ {F}^{( 1 )} - {F}^{( 2 )} \}\end{matrix} ]}^{†} [ \begin{matrix}Re \{ r - {f}^{( 0 )} \} \\ Im \{ r - {f}^{( 0 )} \}\end{matrix} ] ,$ | |
| | | [where\tilde{λ} =[\tilde{λ}₁^{T}, \tilde{λ}₂^{T}, \tilde{λ}₃^{T}]^{T}] |
| | \tilde{λ}ₘ⁽ⁱ⁾ = Re{\tilde{λ}ₘ⁽ⁱ⁾} + jIm{\tilde{λ}ₘ⁽ⁱ⁾}, | |
| | \tilde{λ}ₘ⁽ⁱ⁾ = \tilde{λ}ₘ⁽ⁱ⁾/max_{q=1 . . . M;q≠m} \tilde{λ}_{mq}⁽ⁱ⁾, \tilde{λ}ₘₘ⁽ⁱ⁾ = 1, | |
| | | [normalization to avoid numerical problems] |
| | ã₂ₘ⁽ⁱ⁾ = \tilde{B}₂ₘ⁽ⁱ⁻¹⁾\tilde{λ}ₘ⁽ⁱ⁾, | |
| | | [calculate new estimate of reflection coefficients] |

end if

\tilde{B}₂ₘ⁽ⁱ⁾ = [G(a₁₁, ã₂₁⁽ⁱ⁾)\tilde{θ}₁⁽ⁱ⁾ . . . G(a_{1M}, ã_{2M}⁽ⁱ⁾)\tilde{θ}_{M}⁽ⁱ⁾],

[calculate new estimate of PA output signals]

[\tilde{r}₁⁽ⁱ⁾ \tilde{r}₂⁽ⁱ⁾ \tilde{r}₃⁽ⁱ⁾] = \tilde{B}_{2M}⁽ⁱ⁾[η₁ η₂ η₃],

[calculate new estimate of received signals]

NMSE = max_{l=1,2,3} {NMSE(rₗ, \tilde{r}ₗ⁽ⁱ⁾)},

[evaluate accuracy]

end while

Once the amplifier coefficients and the reflection coefficients are estimated or known, the model of the non-linear amplifier characteristics is complete and the digital pre-distortion parameters may be determined using any suitable approach. Examples of such approaches include the MILA (Model-based Indirect Learning Algorithm, described in P. Landin, A. Mayer, and T. Eriksson, “MILA—A Noise Mitigation Technique for RF Power Amplifier Linearization,” in International Multi-Conference on Systems, Signals & Devices, Conference on Communication & Signal Processing, 2014) and other DLA (Direct Learning Algorithm) based methods (which may involve model inversion).

Typically, the amplifier coefficients and the reflection coefficients are updated at a similar (or the same) frequency as the pre-distortion parameters. Typically, the process of determining the pre-distortion parameters may be continuously performed in an iterative manner or they may be updated responsive to an triggering event (e.g. detection of that the channel has changed, regular time intervals, detection that the DPD does not fulfil some performance requirement, etc.).

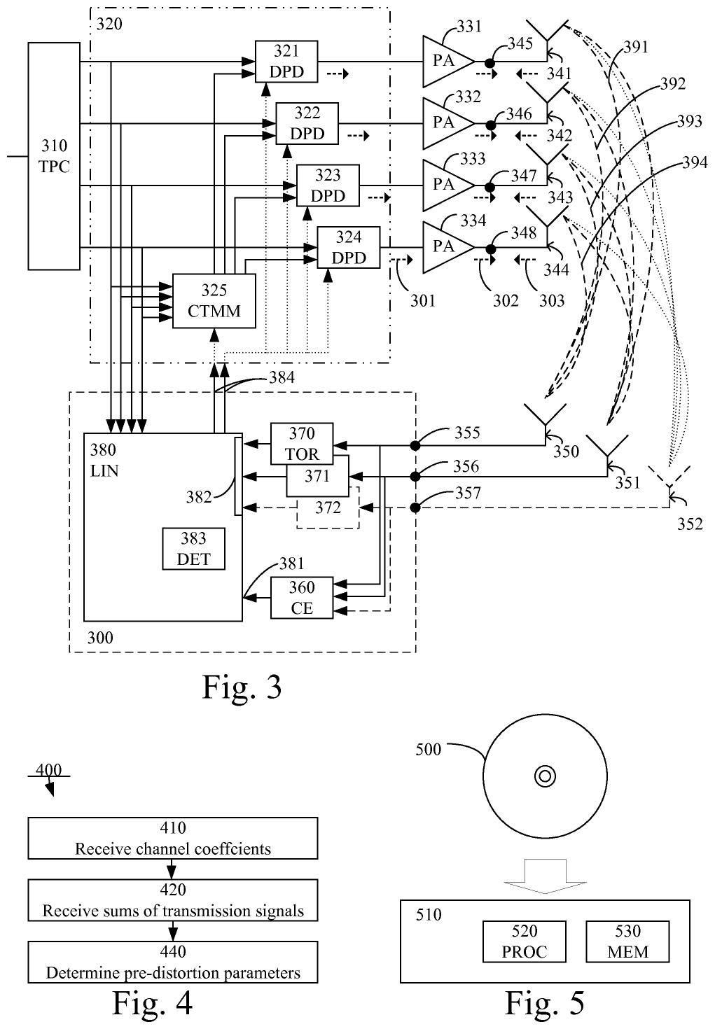

FIG. 4 illustrates an example method 400 according to some embodiments. The example method may, for example, be performed by a linearization device 380 or an arrangement 300 as described and exemplified in connection to FIG. 3, and any features described in connection with FIG. 3 may be equally applicable to the example method 400 according to various embodiments.

The example method 400 is for determining pre-distortion parameters associated with a plurality of non-linear amplifiers, each associated with a non-linear transfer function defining an output of the non-linear amplifier based on an input of the non-linear amplifier and based on a reflection signal for the non-linear amplifier, as described above.

In step 410, a plurality of channel coefficients are received (e.g. via a first port of the linearization device). The plurality of channel coefficients are indicative of channel characteristics of a plurality of communication paths between the plurality of non-linear amplifiers and two or more transmit observation receivers, wherein each transmit observation receiver is configured to receive a sum of transmission signals generated by the plurality of non-linear amplifiers and transferred over the communication paths between the plurality of non-linear amplifiers and the transmit observation receiver.

In step 420, the sums of transmission signals is received from the transmit observation receiver (e.g. via a second port of the linearization device).

In step 440, the pre-distortion parameters are determined based on the received plurality of channel coefficients, the received sums of transmission signals, and a model of the non-linear transfer functions of the non-linear amplifiers.

As described and exemplified above, the method may further comprise estimating the plurality of channel coefficients. Typically, a recursive procedure may be applied where intermediate amplifying coefficients are determined based on initially defined reflection coefficients, intermediate reflection coefficients are determined based on the intermediate amplifying coefficients, refined amplifying coefficients are determined recursively based on previous reflection coefficients, and refined reflection coefficients are determined recursively based on previous amplifying coefficients. Such recursion may, for example, continue a predefined number of times and/or until some stopping criterion is met.

The described embodiments and their equivalents may be realized in software or hardware or a combination thereof. The embodiments may be performed by general purpose circuitry. Examples of general purpose circuitry include digital signal processors (DSP), central processing units (CPU), co-processor units, field programmable gate arrays (FPGA) and other programmable hardware. Alternatively or additionally, the embodiments may be performed by specialized circuitry, such as application specific integrated circuits (ASIC). The general purpose circuitry and/or the specialized circuitry may, for example, be associated with or comprised in an apparatus such as a wireless transmitter node (e.g. a network node) or a cloud based server node.

Embodiments may appear within an electronic apparatus (such as a wireless transmitter node or a cloud based server node) comprising arrangements, circuitry, and/or logic according to any of the embodiments described herein. Alternatively or additionally, an electronic apparatus (such as a wireless transmitter node or a cloud based server node) may be configured to perform methods according to any of the embodiments described herein.

According to some embodiments, a computer program product comprises a computer readable medium such as, for example a universal serial bus (USB) memory, a plug-in card, an embedded drive or a read only memory (ROM). FIG. 5 illustrates an example computer readable medium in the form of a compact disc (CD) ROM 500. The computer readable medium has stored thereon a computer program comprising program instructions. The computer program is loadable into a data processor (PROC) 520, which may, for example, be comprised in a wireless transmitter node or a cloud based server node. When loaded into the data processing unit, the computer program may be stored in a memory (MEM) 530 associated with or comprised in the data-processing unit. According to some embodiments, the computer program may, when loaded into and run by the data processing unit, cause execution of method steps according to, for example, the method illustrated in FIG. 4 or otherwise described herein.

Generally, all terms used herein are to be interpreted according to their ordinary meaning in the relevant technical field, unless a different meaning is clearly given and/or is implied from the context in which it is used.

Reference has been made herein to various embodiments. However, a person skilled in the art would recognize numerous variations to the described embodiments that would still fall within the scope of the claims.

For example, the method embodiments described herein discloses example methods through steps being performed in a certain order. However, it is recognized that these sequences of events may take place in another order without departing from the scope of the claims. Furthermore, some method steps may be performed in parallel even though they have been described as being performed in sequence. Thus, the steps of any methods disclosed herein do not have to be performed in the exact order disclosed, unless a step is explicitly described as following or preceding another step and/or where it is implicit that a step must follow or precede another step.

In the same manner, it should be noted that in the description of embodiments, the partition of functional blocks into particular units is by no means intended as limiting. Contrarily, these partitions are merely examples. Functional blocks described herein as one unit may be split into two or more units. Furthermore, functional blocks described herein as being implemented as two or more units may be merged into fewer (e.g. a single) unit.

Any feature of any of the embodiments disclosed herein may be applied to any other embodiment, wherever suitable. Likewise, any advantage of any of the embodiments may apply to any other embodiments, and vice versa.

Hence, it should be understood that the details of the described embodiments are merely examples brought forward for illustrative purposes, and that all variations that fall within the scope of the claims are intended to be embraced therein.

1-20. (canceled)

21. A linearization device configured to determine pre-distortion parameters associated with a plurality of non-linear amplifiers, each associated with one of a plurality of transmit antenna elements and with a non-linear transfer function defining an output of the non-linear amplifier based on an input of the non-linear amplifier and based on a reflection signal for the non-linear amplifier, resulting from mutual couplings among the plurality of transmit antenna elements, the linearization device comprising:
a first port configured to receive a plurality of channel coefficients indicative of channel characteristics of a plurality of communication paths between the plurality of non-linear amplifiers and two or more transmit observation receivers, wherein each transmit observation receiver is configured to receive a sum of transmission signals generated by the plurality of non-linear amplifiers and transferred over the communication paths between the plurality of non-linear amplifiers and the transmit observation receiver;
a second port configured to receive the sums of transmission signals from the transmit observation receivers; and
determination circuitry configured to determine the pre-distortion parameters based on the received plurality of channel coefficients, the received sums of transmission signals, and a model of the non-linear transfer functions of the non-linear amplifiers.

22. The linearization device of claim 21, wherein the model is represented, for each of the non-linear amplifiers, by a plurality of amplifying coefficients in a space spanned by a regression matrix of the inputs and the reflection signals.

23. The linearization device of claim 22, wherein each reflection signal is modeled as a linear function of the outputs of the plurality of non-linear amplifiers, the linear function being defined by reflection coefficients.

24. The linearization device of claim 23, wherein the determination circuitry is further configured to determine the reflection coefficients by:
defining initial reflection coefficients;
determining intermediate amplifying coefficients based on the initial reflection coefficients;
determining intermediate reflection coefficients based on the intermediate amplifying coefficients; and
recursively determining refined amplifying coefficients based on previous reflection coefficients, and refined reflection coefficients based on previous amplifying coefficients.

25. The linearization device of claim 22, wherein the linearization device is configured to determine the pre-distortion parameters based on the amplifying coefficients.

26. The linearization device of claim 25, wherein the linearization device is configured to determine the amplifying coefficients based on N samples of the sums of transmission signals received by the transmit observation receivers via L receive antenna ports by:
determining, for each of the plurality of non-linear amplifiers, a Kronecker product between a column vector having as elements the corresponding estimated channel coefficients and the regression matrix;
calculating a generalized pseudo-inverse of a matrix formed by concatenating the determined Kronecker products of the plurality of non-linear amplifiers; and
determining a matrix product between the calculated generalized pseudo-inverse and a column vector having as elements the N samples of the sums of transmission signals from each of the L receive antenna ports.

27. The linearization device of claim 21, wherein the plurality of communication paths are radio communication paths between the plurality of non-linear amplifiers and the transmit observation receivers via a corresponding plurality of transmit antenna elements and at least two receive antenna elements.

28. An apparatus for a wireless transmitter node, the wireless transmitter node comprising at least two receive antenna ports, each connectable to a corresponding receive antenna element, and a plurality of transmit antenna ports, each connectable to a corresponding transmit antenna element of an active antenna array having a plurality of transmit antenna elements, each transmit antenna port being associated with a respective transmitter branch, wherein each transmitter branch comprises:
a non-linear amplifier associated with one of the plurality of transmit antenna elements and with a non-linear transfer function defining an output of the non-linear amplifier based on an input of the non-linear amplifier and based on a reflection signal for the non-linear amplifier, resulting from mutual couplings among the plurality of transmit antenna elements; and
digital pre-distortion circuitry configured to compensate the non-linear transfer function by pre-distorting the signal of the transmitter branch based on pre-distortion parameters;
the apparatus comprising:
a channel estimator configured to estimate a plurality of channel coefficients indicative of channel characteristics of a plurality of communication paths between the plurality of non-linear amplifiers and two or more transmit observation receivers;
the two or more transmit observation receivers, each associated with one of the at least two receive antenna ports and each configured to receive a sum of transmission signals generated by the plurality of non-linear amplifiers and transferred over the communication paths between the plurality of non-linear amplifiers and the transmit observation receiver; and
the linearization device of claim 21, wherein the first port is connected to the channel estimator and the second port is connected to the transmit observation receiver and wherein the linearization device is configured to provide the determined pre-distortion parameters to the digital pre-distortion circuitry of the transmitter branches.

29. The apparatus of claim 28 further comprising the at least two receive antenna ports and the at least two receive antenna elements.

30. A wireless transmitter node comprising the apparatus of claim 28 and further comprising a linearization device, the linearization device comprising:
a first port configured to receive a plurality of channel coefficients indicative of channel characteristics of a plurality of communication paths between the plurality of non-linear amplifiers and two or more transmit observation receivers, wherein each transmit observation receiver is configured to receive a sum of transmission signals generated by the plurality of non-linear amplifiers and transferred over the communication paths between the plurality of non-linear amplifiers and the transmit observation receiver;
a second port configured to receive the sums of transmission signals from the transmit observation receivers; and
determination circuitry configured to determine the pre-distortion parameters based on the received plurality of channel coefficients, the received sums of transmission signals, and a model of the non-linear transfer functions of the non-linear amplifiers.

31. A cloud based server node comprising the linearization device of claim 21, wherein the cloud based server node is configured to provide the determined pre-distortion parameters to a wireless transmitter node.

32. A method for a linearization device for determining pre-distortion parameters associated with a plurality of non-linear amplifiers, each associated with one of a plurality of transmit antenna elements and with a non-linear transfer function defining an output of the non-linear amplifier based on an input of the non-linear amplifier and based on a reflection signal for the non-linear amplifier, resulting from mutual couplings among the plurality of transmit antenna elements, the method comprising:
receiving, via a first port of the linearization device, a plurality of channel coefficients indicative of channel characteristics of a plurality of communication paths between the plurality of non-linear amplifiers and two or more transmit observation receivers, wherein each transmit observation receiver is configured to receive a sum of transmission signals generated by the plurality of non-linear amplifiers and transferred over the communication paths between the plurality of non-linear amplifiers and the transmit observation receiver;
receiving, via a second port of the linearization device, the sums of transmission signals from the transmit observation receiver; and
determining the pre-distortion parameters based on the received plurality of channel coefficients, the received sums of transmission signals, and a model of the non-linear transfer functions of the non-linear amplifiers.

33. The method of claim 32, wherein the model is represented, for each of the non-linear amplifiers, by a plurality of amplifying coefficients in a space spanned by a regression matrix of the inputs and the reflection signals.

34. The method of claim 33, wherein each reflection signal is modelled as a linear function of the outputs of the plurality of non-linear amplifiers, the linear function being defined by reflection coefficients.

35. The method of claim 34, further comprising determining the reflection coefficients by:
defining initial reflection coefficients;
determining intermediate amplifying coefficients based on the initial reflection coefficients;
determining intermediate reflection coefficients based on the intermediate amplifying coefficients; and
recursively determining refined amplifying coefficients based on previous reflection coefficients, and refined reflection coefficients based on previous amplifying coefficients.

36. The method of claim 33, wherein the pre-distortion parameters are determined based on the amplifying coefficients.

37. The method of claim 36, wherein determining the amplifying coefficients based on N samples of the sums of transmission signals received by the transmit observation receiver via L receive antenna ports comprises:
determining, for each of the plurality of non-linear amplifiers, a Kronecker product between a column vector having as elements the corresponding estimated channel coefficients and the regression matrix;
calculating a generalized pseudo-inverse of a matrix formed by concatenating the determined Kronecker products of the plurality of non-linear amplifiers; and
determining a matrix product between the calculated generalized pseudo-inverse and a column vector having as elements the N samples of the sums of transmission signals from each of the L receive antenna ports.

38. The method of claim 32, wherein the plurality of communication paths are radio communication paths between the plurality of non-linear amplifiers and the transmit observation receiver via a corresponding plurality of transmit antenna elements and at least two receive antenna elements.

39. The method of claim 32 further comprising estimating the plurality of channel coefficients.

40. A computer program product comprising a non-transitory computer readable medium, having thereon a computer program comprising program instructions, the computer program being loadable into a data processing unit and configured to cause execution of the method according to claim 32 when the computer program is run by the data processing unit.
